(19) United States
(12) Patent Application Publication
(10) Pub. No.: US 2015/0333194 A1
(43) Pub. Date: Nov. 19, 2015

(54) METHOD FOR MANUFACTURING NANO-STRUCTURAL FILM IN SOLAR CELL

(71) Applicant: NATIONAL CHENG KUNG UNIVERSITY, Tainan City (TW)

(72) Inventors: YU-SHUN CHENG, TAINAN CITY (TW); CHIE GAU, TAINAN CITY (TW); CHI-FENG CHANG, TAINAN CITY (TW); CHIH-HUNG CHUANG, TAINAN CITY (TW); YU-CHENG HONG, TAINAN CITY (TW); KAI-HUNG CHEN, TAINAN CITY (TW)

(73) Assignee: NATIONAL CHENG KUNG UNIVERSITY, Tainan City (TW)

(21) Appl. No.: 14/279,427

(22) Filed: May 16, 2014

(51) Int. Cl. H01L 31/0236; H01L 31/0232

(52) U.S. Cl. CPC H01L 31/02366; H01L 31/02327

(57) ABSTRACT

A method for manufacturing a nanostructural film in a solar cell is revealed herein to include steps of forming an optical layer on a surface of a solar cell, heating a substrate of the solar cell at a temperature ranging from 100° C. to 200° C., imprinting a micro-pattern of a brightness enhanced film (BEF) on the optical layer in a vacuum environment, wherein the micro-pattern has a triangular pyramid shape and arranged periodically on the optical layer, finally removing the BEF after cooling so that the optical layer is formed into a nanostructured film corresponding to the micro-pattern of the BEF.

### BACKGROUND OF THE INVENTION

1. Fields of the Invention

The present invention relates to a method for manufacturing a nanostructural film in a solar cell especially by means of poly(dimethylsiloxane) (PDMS) or ethylene vinyl acetate (EVA). The method of the present invention can be repeatedly done in a general environment without special and expensive equipment or devices to save the cost. The nanostructural film can be directly manufactured on the optical layer of the solar cell so that the solar cell generates the light concentration effect to increase routes through which the light inside the solar cell travel, effectively reduce the light reflectivity and enhance the photoelectric conversion efficiency thereof.

2. Descriptions of Related Art

The sun is the source of life, and human being cannot live without the sun. Although there are no immediately exhausted crises for the fossil fuels, e.g. oil or coal, on which the life around the world rely, the carbon dioxide emission from the excessive use of the fossil fuel has already caused the serious greenhouse effect to become the culprit in the earth's warming temperatures. Furthermore, since the price of crude oil continued to rise in recent years and nuclear power plant safety concern, looking for alternative energy sources has become imperative. Alternative energy sources, such as wind, hydro, geothermal, biodiesel, solar cells and so on, to be called as green energy, have attracted considerable attention over recent years, among which the solar cell is the most promising due to its high theoretical efficiency and mature technology.

The solar cell can transform the solar energy into electrical energy based on the photoelectric effect of materials. The photoelectric effect is the phenomenon that light shines into the material to increase conductive carriers. In terms of the semiconductor materials, as the energy of the light is larger than the energy gap of the semiconductors, the free elector-hole pairs are generated in the interior. However, these elector-hole pairs can be recombined soon or captured by the carriers in the semiconductors to become vanished. If an internal electric field is applied at this time, the carriers will be quickly led out before vanished. The internal electric field is generated in the joint interface between p-type and n-type semiconductors, and a so-called solar cell uses the internal electric field to extract effectively the current to induce the electricity.

However, currently the biggest problem of the solar cell is that its luminous efficiency cannot continuously be improved. When light shines on the surface of the solar cell, the large difference between the refractive index of air (refractive index, n=1) and of a silicon substrate (refractive index, n=3.42) will generate a large amount of Fresnel reflection; in other word, part of the incident light is straightly reflected and the rest thereof is absorbed by the solar cell to generate electron-hole pairs. This factor not only causes an unideal photoelectric conversion efficiency of the solar cell but also increases power generation cost to obstruct the application and development of the solar cell in daily life.

In order to change the direction of the incident light from direct to oblique to reduce the surface reflection and increase the amount of light absorbed by solar cell, the single layer or multiple layers of the dielectric materials with the refractive index between that of the substrate and of air are coated on the surface of the traditional solar cell, for example, silicon nitride (Si₃N₄), silicon oxide (SiOₓ), and titanium oxide (TiOₓ). The method of destructive interference is used to achieve the effect of anti-reflection by the traditional solar cell and to enhance the photoelectric conversion efficiency. However, the traditional manufacturing processes for films must be done in a high vacuum environment e.g. semiconductor clean rooms. The thickness of films must be precisely controlled in the traditional manufacturing processes. Films with an adequate refractive index are lacking for use in the traditional manufacturing processes. All the aforesaid are the main disadvantages for the traditional processes for making solar cells. Applications of anti-reflection films on the solar cell are thus substantially restricted due to such traditional processes for making solar cells.

### SUMMARY OF THE INVENTION

Therefore, in order to effectively manufacture a nanostructural film to be affixed on a solar cell under a simplified process at a low cost, enhance the photoelectric conversion efficiency of the solar cell and reduce the light reflection, a primary goal of the present invention is to provide a method for manufacturing a nanostructural film in a solar cell, especially by use of poly(dimethylsiloxane) (PDMS) or ethylene vinyl acetate (EVA). The method of the present invention can be repeatedly done in a general environment without special and expensive equipment or devices to save the cost. The nanostructural film can be directly manufactured on an optical layer of the solar cell so that the solar cell generates the light concentration effect to increase routes through which the light inside the solar cell travel, effectively reduce the light reflectivity and enhance the photoelectric conversion efficiency thereof.

In order to achieve the above objectives, a method for manufacturing a nanostructural film in a solar cell is present herein and includes following steps as forming an optical layer on a surface of a solar cell, heating a substrate of the solar cell at a temperature ranging from 100° C. to 200° C., imprinting a micro-pattern of a brightness enhanced film (BEF) on the optical layer in a vacuum environment, wherein the micro-pattern has a triangular pyramid shape and is periodically arranged on the optical layer, and finally removing the brightness enhanced film after cooling so that the optical layer is formed into a nanostructural film corresponded to the micro-pattern to complete a method for manufacturing a nanostructural film in a solar cell.

The optical layer made of poly(dimethylsiloxane) (PDMS) is coated on the surface of a solar cell by use of a spin coater at a speed of 1000 rpm.

The optical layer made of ethylene vinyl acetate (EVA) is horizontally laid on the surface of the solar cell. Then the brightness enhanced film is laminated on the optical layer under a pressure ranging from 80 KPa to 100 KPa for 10 to 15 minutes.

The substrate of the solar cell is heated at a temperature of 150° C.

The micro-pattern of the brightness enhanced film is a brightened element with a prism structure for gathering light, and it has a periodical pitch ranging from 17 μm to 48 μm.

Accordingly, the present invention uses a mold having a nanostructured surface to prepare the nanostructural film by imprint molding in cooperation with optical layers each having a refractive index between those of the substrate and air. The nanostructural film can be directly affixed on the surface of the solar cell so that the solar cell generates the light concentration effect to increase routes through which the light inside the solar cell travel, effectively reduce the light reflectivity and enhance the photoelectric conversion efficiency thereof. In addition, the present invention uses materials of ethylene vinyl acetate (EVA) or poly(dimethylsiloxane) (PDMS) to prepare the optical layers in manufacture of the nanostructured film. Unlike traditional nanostructures mostly manufactured by the lithography process of the semiconductor industry, the method of the present invention can be repeatedly done in a general environment without special and expensive equipment or devices; in other words, it is simplified to save much more costs for manufacturing solar cells. Furthermore, a concave or convex spherical manostructural film or other films having various spherical nanostructures can be used in the present invention to enhance the photoelectric conversion efficiency of the solar cell. Owing to no significant results for use of concave spherical nanostructure or convex spherical nanostructure in enhancing the photoelectric conversion efficiency of the solar cell, either light gathering or light scattering enable to increase routes of light to further enhance the light absorption and effectively improve the current density of the solar cell.

### BRIEF DESCRIPTION OF THE DRAWINGS

The structure and the technical means adopted by the present invention to achieve the above and other objects can be best understood by referring to the following detailed description of the preferred embodiments and the accompanying drawing, wherein

FIG. 1 is a flow chart showing steps of an embodiment of a method for manufacturing a nanostructural film in a solar cell according to the present invention;

FIG. 2 is a schematic drawing showing formation of an optical layer of an embodiment of a method for manufacturing a nanostructural film in a solar cell according to the present invention;

FIG. 3 is a schematic drawing showing heating a substrate of an embodiment of a method for manufacturing a nanostructural film in a solar cell according to the present invention;

FIG. 4 is a schematic drawing showing copying a brightness enhanced film of an embodiment of a method for manufacturing a nanostructural film in a solar cell according to the present invention;

FIG. 5 is a schematic drawing showing formation of a nanostructural film of an embodiment of a method for manufacturing a nanostructural film in a solar cell according to the present invention;

FIG. 6 is a schematic drawing showing formation of a ball micro-pattern molding of an embodiment of a method for manufacturing a nanostructural film in a solar cell according to the present invention;

FIG. 7 is a schematic drawing showing imprint of a nanostructural film of an embodiment of a method for a nanostructural film in a solar cell according to the present invention;

FIG. 8 is a schematic drawing showing formation of a convex spherical nanostructured film of an embodiment of a method for a nanostructural film in a solar cell according to the present invention;

FIG. 9 shows the reflection rate of a PDMS solar cell according to an embodiment of the present invention;

FIG. 10 is a diagram illustrating electrical characteristics of an exemplary solar cell formed with the PDMS nanostructured film;

FIG. 11 is a diagram illustrating comparative reflection rate of exemplary solar cells respectively formed with the optical layer of PDMS or EVA;

FIG. 12 is a diagram illustrating comparative electrical characteristics of exemplary solar cells respectively formed with the optical layer of PDMS or EVA.

### DETAILED DESCRIPTION OF THE PREFERRED EMBODIMENT

First, about the following description of the embodiment, it should be understood that when a layer (or a film) or a structure is deposited on or under another substrate, another layer (or film) or another structure, it can be directly disposed in the other substrate, layer (or film), or another structure, or indirectly disposed on more than one intermediate layers between both. Please refer to the location of each layer in brief description of the figures.

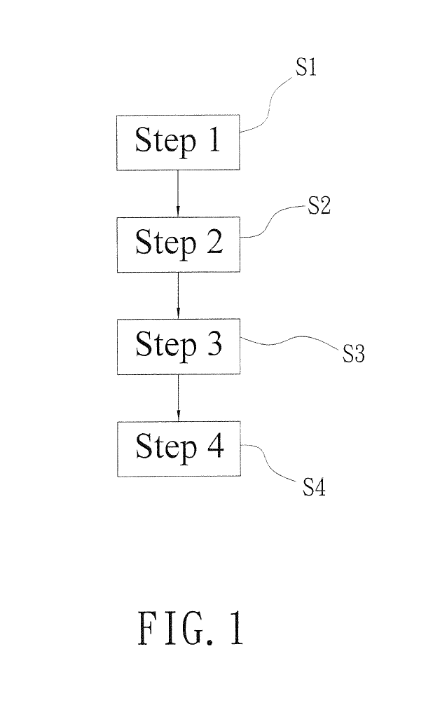

As referring to FIG. 1, a flow chart showing steps of an embodiment of a method for manufacturing a nanostructural film in a solar cell according to the present invention, includes following steps.

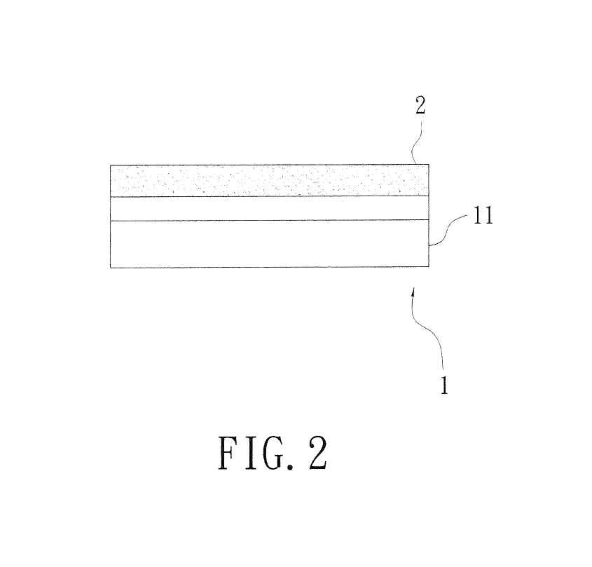

Step one (S1): forming an optical layer (2) on a surface of a solar cell (1); as referring to FIG. 2, a schematic drawing showing formation of an optical layer of an embodiment of a method for manufacturing a nanostructural film in a solar cell according to the present invention, wherein the optical layer (2) in the present invention is made of poly(dimethylsiloxane) (PDMS) or ethylene vinyl acetate (EVA). In the preferred embodiment of the present invention, ethylene vinyl acetate (EVA) is horizontal laid on the surface of the solar cell (1) as the purpose of the optical layer (2), wherein EVA is a new hot melt adhesive film used in the package of the solar cell. Ethylene vinyl acetate is a raw material, after adding various assistants and heating extrusion, it can be applied in the general monocrystalline silicon and polycrystalline silicon solar cell and the module of the thin-film solar cell. EVA has the advantages of durability, high adhesion strength, high transparency and low shrinkage, and contributes to the highest efficiency performance of solar cell module. In another preferred embodiment of the present invention, poly(dimethylsiloxane) (PDMS) is uniformly coated on the surface of the solar cell (1) by use of a spin coater at a spin-coating speed of 1000 rpm for 30 seconds as the purpose of the optical layer (2), wherein PDMS is a polymeric organosilicon compound and commonly referred to as an organic silicon, it has an optical transparency characteristic, and it is consider as the material of inert, non-toxic and non-flammable, and it is widely used silicon-based organic polymer. When liquid, PDMS is a viscous liquid, known as silicone oil, and it is in solid after curing by baking. The solid PDMS is a silicone with the characteristics of non-toxic, hydrophobic and inert, and it is a non-flammable transparent elastomer. The manufacturing process of PDMS is simple and fast, the material cost is much lower than a silicon wafer, and it has a good light transmission, good biocompatibility and easily engagement with a variety of materials at room temperature. Because it has high structural flexibility due to lower young's module, it is often used in a microfluidic system of bio-MEMS, a soft lithography process and nanostructure manufacturing, and it has wide range of applications;

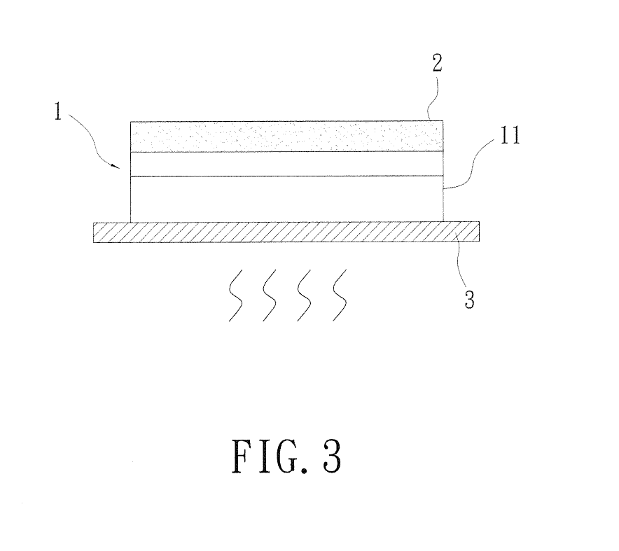

Step two (S2): heating the substrate (11) of the solar cell (1) at a temperature ranging from 100° C. to 200° C.; as referring to FIG. 3, a schematic drawing showing heating a substrate of an embodiment of a method for manufacturing a nanostructural film in a solar cell according to the present invention, wherein the heating process is to put the solar cell (1) on a heating plate (3) for heating to 150° C.;

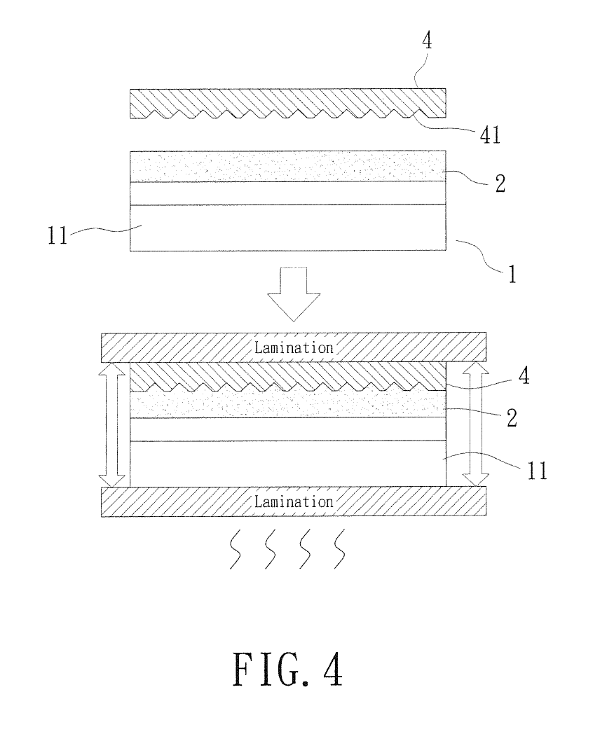

Step three (S3): imprinting a micro-pattern (41) of a brightness enhanced film (BEF) (4) on the optical layer (2) in a vacuum environment, wherein the micro-pattern (41) has a triangular pyramid shape and is periodically arranged on the optical layer (2); the brightness enhanced film (4) is known as an optical brightness enhanced film, and it is optical element used in LCD backlight module. On the premise that without increasing the power consumption of the system, the main function is to effectively improve the problem of light source wasted in other components within the LCD. The BEF (4) manufacturing process is that an acrylic resin layer is coated on the optical film, and then use a wheel with a precast micro-pattern (41) to imprint, and the subtle prism structure is finally hardened by high energy of UV, wherein the main function of the prism structure is to focus the scattered light emitted from a lightguide in the LCD by the refraction and internal total reflection mechanism, so that the viewer can obtain the optimum brightness within the normal operating range. As referring to FIG. 4, a schematic drawing showing copying a brightness enhanced film of an embodiment of a method for manufacturing a nanostructural film in a solar cell according to the present invention. In the preferred embodiment of the present invention, ethylene vinyl acetate (EVA) is selected as the optical layer (2) of the solar cell (1), then the brightness enhanced film (4) made from the micro-pattern (41) has a triangular pyramid shape and is periodically arranged as an imprint molding, wherein the periodical triangular pyramid structure is a brightened element with a prism structure for gathering light and has a pitch ranging from 17 μm to 48 μm, and the brightness enhanced film (4) is imprinted on the optical layer (2) with a lamination process under a pressure ranging from 80 KPa to 100 KPa, and the micro-pattern (41) of the brightness enhanced film (4) is imprinted on the optical layer (2) after 10 to 15 minutes; and

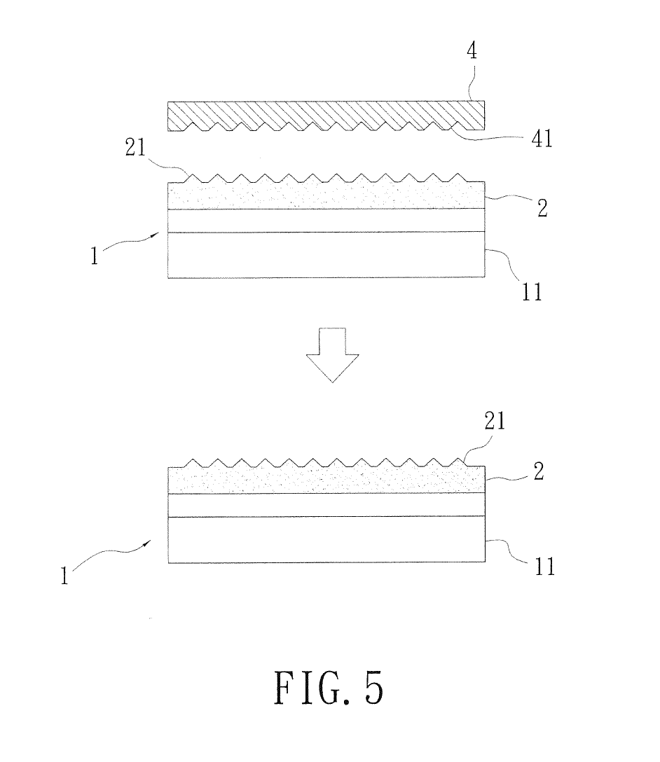

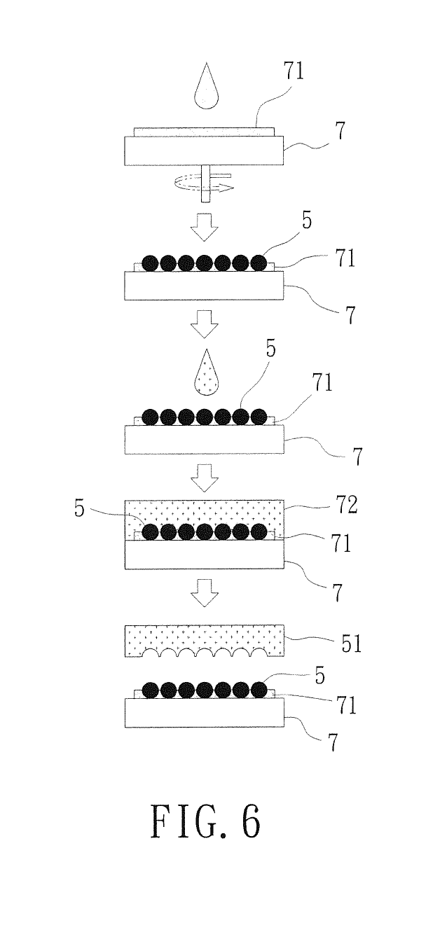

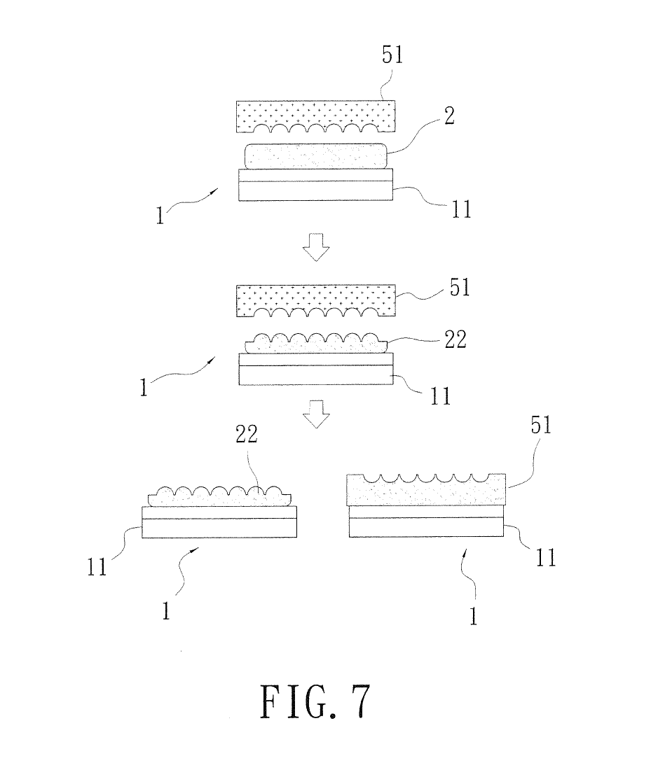

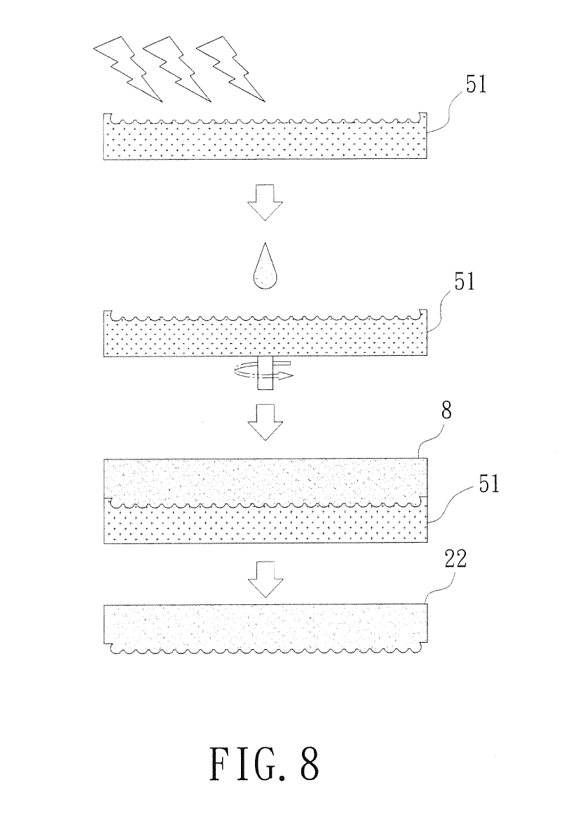

Step four (S4): removing the BEF (4) after cooling so that the optical layer (2) is formed into a nanostructural film (21) corresponding to the micro-pattern (41) of the BEF (4) to complete a method for manufacturing a nanostructural film in a solar cell; as referring to FIG. 5, a schematic drawing showing formation of a nanostructural film of an embodiment of a method for manufacturing a nanostructural film in a solar cell according to the present invention. In addition, since the main principle of the present invention makes the action of imprint a molding with the micro-pattern (41), wherein the molding with the micro-pattern (41) is the structure of a ball micro-pattern molding adhered commercially available small steel ball (5) in the size of 1 mm, a pyramid micro-pattern diffusion plate (6) used in a flash lamp and a the brightness enhanced film (4) without limitation to the generality of the foregoing. As referring to FIG. 6, a schematic drawing showing formation of a ball micro-pattern molding of an embodiment of a method for manufacturing a nanostructural film in a solar cell according to the present invention, wherein a concave spherical nanostructured film (51) is imprinted from ball micro-pattern of the small steel ball (5), and as referring the patent of “method for manufacturing solar cell with nanostructural film” invented by the present inventor and applied in the same day about the method for manufacturing the molding. The method uses a spin coater to uniformly spin-coat a first PDMS layer (71) on a glass substrate (7), and the small steel ball (5) is adhered onto the first PDMS layer (71), then a second PDMS layer (72) is spin-coated on the small steel ball (5), the second PDMS layer (72) can be cured and released to form a molding of the concave spherical nanostructured film (51), wherein the curing process has a temperature ranging from 90° C. to 110° C. and a time ranging from 30 minutes to 1 hour. The preferred embodiment of the present invention is 90° C. at 1 hour. As referring to FIG. 7, a schematic drawing showing imprint of a nanostructural film of an embodiment of a method for a nanostructural film in a solar cell according to the present invention, wherein the brightness enhanced film (4) of the preferred embodiment of the present invention can be replaced by the concave spherical nanostructured film (51) of PDMS molding to proceed the lamination process of above step three (S3) so that the optical layer (2) can be formed a convex spherical nanostructured film (22) from the concave spherical nanostructured film (51), the solar cell (1) with the convex spherical nanostructured film (22) is formed. In addition, the solar cell (1) with the concave spherical nanostructured film (51) is formed by adhering the concave spherical nanostructured film (51) of PDMS molding. In addition, the molding of the convex spherical nanostructured film (22) can be also manufactured by the method described in the patent of “method for manufacturing solar cell with nanostructural film”. As referring to FIG. 8, a schematic drawing showing formation of a convex spherical nanostructured film of an embodiment of a method for a nanostructural film in a solar cell according to the present invention; including steps of treating the concave spherical nanostructured film (51) of PDMS molding with UV ozone; uniformly spin-coating a third PDMS layer (8) on the s PDMS molding of the concave spherical nanostructured film (51); obtaining a PDMS molding of the convex spherical nanostructured film (22). Furthermore, the concave and convex spherical nanostructured film can be manufactured by the pyramid micro-pattern diffusion plate (6) in the same of the above manufacturing method, and this method will not discuss it. Therefore, it is only one example of the present invention to use the brightness enhanced film (4) as the molding with the micro-pattern (41) without limitation to the generality of the foregoing. As long as the effect and the technical advantages resulted from the imprint molding with the micro-pattern (41) are the same as the preferred embodiment, all changes or modifications should be considered equivalent to the present invention.

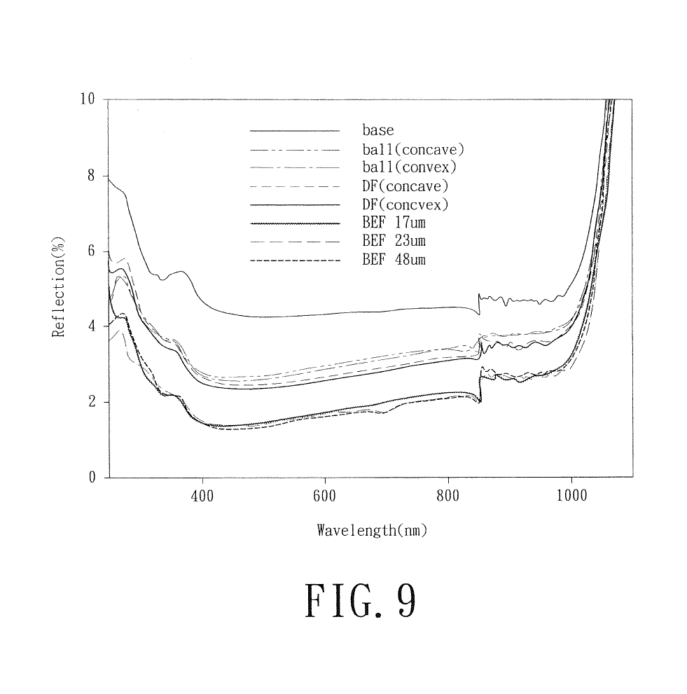

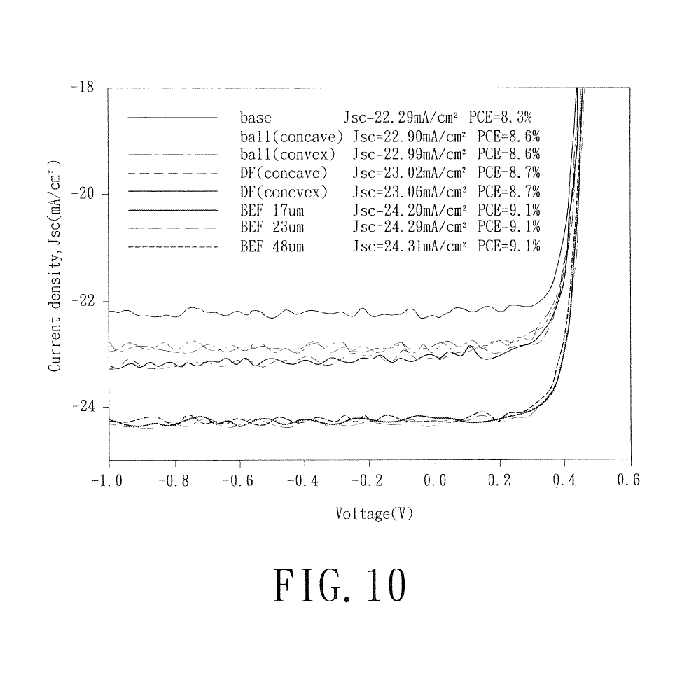

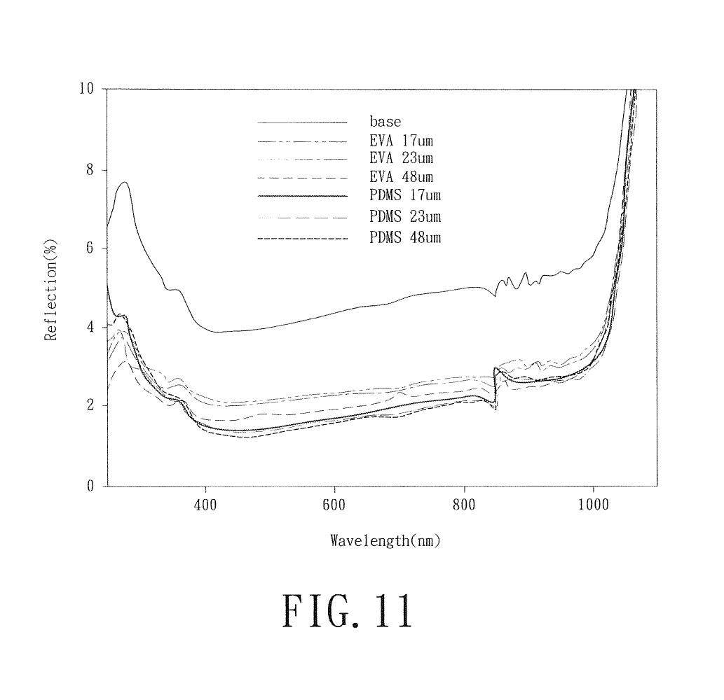

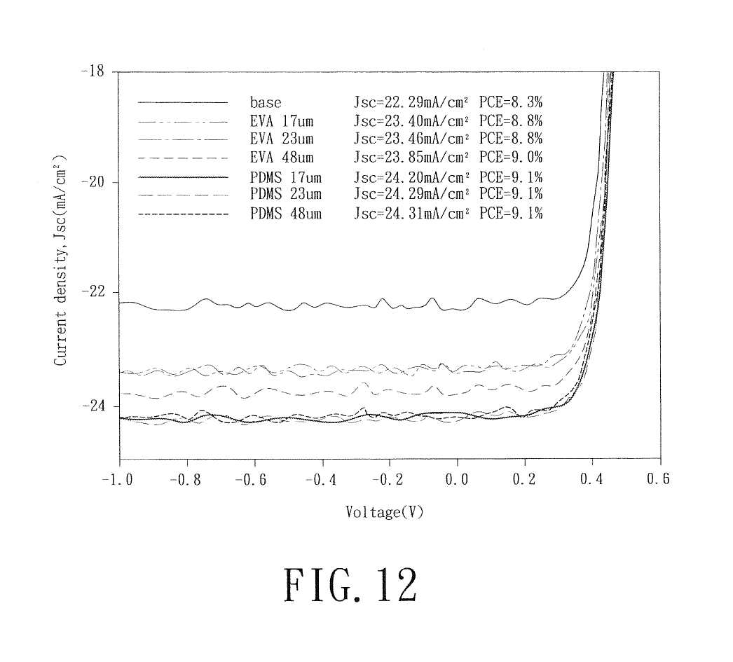

According to the above method for manufacturing a nanostructural film in a solar cell for practical implementation, when the nanostructural film (21) manufactured by different micro-pattern (41) is applied in the solar cell (1), the photoelectric conversion efficiency is obviously enhanced and the reflectance is also apparently improved. Using the PDMS as the optical layer (2) in the embodiment of the present invention, it uses the molding with the micro-pattern (41) to carry out the example for enhancing the photoelectric conversion efficiency. As referring to FIG. 9, the reflection rate of a PDMS solar cell according to an embodiment of the present invention, wherein “base” is expressed as the reflection rate of the solar cell (1) without the nanostructural film (21), “ball (concave)” is expressed as the reflection rate of the solar cell (1) with the concave spherical nanostructured film (51), “ball (convex)” is expressed as the reflection rate of the solar cell (1) with the convex spherical nanostructured film (22), “DF (concave)” is expressed as the reflection rate of the solar cell (1) with the concave pyramid nanostructured film (not shown), “DF (convex)” is expressed as the reflection rate of the solar cell (1) with the convex pyramid nanostructured film (not shown), “BEF 17 μm” is expressed as the reflection rate of the solar cell with the nanostructural film (21) manufactured by the brightness enhanced film (4) with 17 μm periodical pitch, “BEF 23 μm” is expressed as the reflection rate of the solar cell with the nanostructural film (21) manufactured by the brightness enhanced film (4) with 23 μm periodical pitch, and “BEF 48 μm” is expressed as the reflection rate of the solar cell with the nanostructural film (21) manufactured by the brightness enhanced film (4) with 48 μm periodical pitch. As the average reflection rate (%) of the visible light region with a wavelength ranging from 400 nm to 800 nm, the average reflection rate of the solar cell (1) without the nanostructural film (21) is 4.5%, and the average reflection rate of the solar cell (1) with spherical and pyramid micro-pattern combining with PDMS optical layer (2) can be improved to 3%, and the average reflection rate of the solar cell (1) with the micro-pattern (41) of the brightness enhanced film (4) can also be improved to 1.5%. In addition, as referring to FIG. 10, a diagram illustrating electrical characteristics of an exemplary solar cell formed with the PDMS nanostructured film, wherein the type of the nanostructural film (21) represented of each line is the same as FIG. 9. The experiment shows that 0.53V of an open circuit voltage (V_{oc}) in the solar cell (1) and 0.71 of a filling factor (FF) are not increased, and the current density is enhanced from 22.29 mA/cm² of without the nanostructural film (21) to 23 mA/cm² of the with the nanostructural film (21) with spherical and pyramid micro-pattern combining with PDMS optical layer (2), the enhancing effect is to 3%. The average current density of the solar cell manufactured by the micro-pattern (41) of the brightness enhanced film (4) is 24.27 mA/cm², the enhancing effect is to 9%. And the photovoltaic conversion efficiency (PCE) is enhanced from 8.3% to 8.7% and 9.1%. In addition, using the EVA as the optical layer (2) in the embodiment of the present invention, the solar cell (1) manufactured by imprint molding of the brightness enhanced film (4) with periodical pitch 17 μm, 23 μm and 48 μm has the same effect. In addition, as referring to FIG. 11, a diagram illustrating comparative electrical characteristics of exemplary solar cells respectively formed with the optical layer of PDMS or EVA, wherein “base” is expressed as the reflection rate of the solar cell (1) without the nanostructural film (21), “EVA 17 μm” is expressed as the reflection rate of the solar cell (1) with the optical layer (2) of EVA combining with the micro-pattern (41) of the brightness enhanced film (4) with 17 μm periodical pitch, “EVA 23 μm” is expressed as the reflection rate of the solar cell (1) with the optical layer (2) of EVA combining with the micro-pattern (41) of the brightness enhanced film (4) with 23 μm periodical pitch, “EVA 48 μm” is expressed as the reflection rate of the solar cell (1) with the optical layer (2) of EVA combining with the micro-pattern (41) of the brightness enhanced film (4) with 48 μm periodical pitch, “PDMS 17 μm” is expressed as the reflection rate of the solar cell (1) with the optical layer (2) of PDMS combining with the micro-pattern (41) of the brightness enhanced film (4) with 17 μm periodical pitch, “PDMS 23 μm” is expressed as the reflection rate of the solar cell (1) with the optical layer (2) of PDMS combining with the micro-pattern (41) of the brightness enhanced film (4) with 23 μm periodical pitch, and “PDMS 48 μm” is expressed as the reflection rate of the solar cell (1) with the optical layer (2) of PDMS combining with the micro-pattern (41) of the brightness enhanced film (4) with 48 μm periodical pitch. As the average reflection rate (%) of the visible light region with a wavelength ranging from 400 nm to 800 nm, the average reflection rate of the solar cell (1) without the nanostructural film (21) is 4.5%, and the solar cell (1) manufactured by the optical layer (2) of EVA is improved to 2%, and the solar cell (1) manufactured by the optical layer (2) of PDMS is enhanced to 1.5%. In addition, as referring to FIG. 12, a diagram illustrating comparative electrical characteristics of exemplary solar cells respectively formed with the optical layer of PDMS or EVA, wherein the type of the optical layer (2) represented of each line is the same as FIG. 11. The experiment shows that 0.53V of the open circuit voltage (V_{oc}) in the solar cell (1) and 0.71 of the filling factor (FF) are not also increased, and the current density is enhanced from 22.29 mA/cm² of that without the nanostructural film (21) to 23.57 mA/cm² of that with the optical layer (2) of EVA, the enhancing effect is to 6%. And the average current density of the solar cell (1) with the optical layer (2) of PDMS is 24.27 mA/cm², the enhancing effect is to 9%, and the photovoltaic conversion efficiency (PCE) is enhanced from 8.3% to 8.9% and 9.1%.

The above experiment shows that the photovoltaic conversion efficiency of the solar cell (1) with the nanostructural film (21) can be effectively enhanced, wherein no matter there is the nanostructural film (21) or not, even if the photovoltaic conversion efficiency of the solar cell (1) is slightly enhanced by spin-coating a pure optical layer (2), and the enhancement is more obvious by forming the nanostructural film (21). Any type of the nanostructural film (21) can reach the purpose of enhancing the photovoltaic conversion efficiency of the solar cell (1). Furthermore, since the difference of the enhanced range by concave spherical nanostructured film or convex spherical nanostructured film is insignificant, it means that whether light gathering or light scattering can increase the path of light to enhance the absorption of light in the solar cell and effectively to improve the current density.

Compared with techniques available now, the present invention has the following advantages:
1. The present invention uses a mold having a nanostructured surface to prepare the nanostructural film by imprint molding in cooperation with optical layers each having a refractive index between those of the substrate and air. The nanostructural film can be directly affixed on the surface of the solar cell so that the solar cell generates the light concentration effect to increase routes through which the light inside the solar cell travel, effectively reduce the light reflectivity and enhance the photoelectric conversion efficiency thereof.
2. The present invention uses materials of ethylene vinyl acetate (EVA) or poly(dimethylsiloxane) (PDMS) to prepare the optical layers in manufacture of the nanostructured film. Unlike traditional nanostructures mostly manufactured by the lithography process of the semiconductor industry, the method of the present invention can be repeatedly done in a general environment without special and expensive equipment or devices; in other words, it is simplified to save much more costs for manufacturing solar cells.
3. A concave or convex spherical manostructural film or other films having various spherical nanostructures can be used in the present invention to enhance the photoelectric conversion efficiency of the solar cell. Owing to no significant results for use of concave spherical nanostructure or convex spherical nanostructure in enhancing the photoelectric conversion efficiency of the solar cell, either light gathering or light scattering enable to increase routes of light to further enhance the light absorption and effectively improve the current density of the solar cell.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

1. A method for manufacturing a light-concentrating film on a solar cell prepared by an imprint molding process, comprising:
(S1): applying an optical layer directly on a surface of a solar cell;
(S2): heating a substrate of the solar cell at a temperature ranging from 100° C. to 200° C.;
(S3): subsequent to the heating, imprinting a micro-pattern of a brightness enhanced film (BEF) on the optical layer in a vacuum environment, wherein the micro-pattern has a triangular pyramid shape and is periodically arranged on the optical layer; and
(S4): removing the BEF after cooling so that the optical layer is formed into a light-concentrating film corresponding to the micro-pattern of the BEF to complete a method for manufacturing a light-concentrating film on a solar cell.

2. The method as claimed in claim 1, wherein the optical layer is coated on the surface of a solar cell by use of a spin coater at a speed of 1000 rpm.

3. The method as claimed in claim 2, wherein the optical layer is made of poly(dimethylsiloxane) (PDMS).

4. The method as claimed in claim 1, wherein the optical layer is horizontally laid on the surface of the solar cell.

5. The method as claimed in claim 4, wherein the optical layer is made of ethylene vinyl acetate (EVA).

6. (canceled)

7. The method as claimed in claim 1, wherein the temperature for heating the substrate of the solar cell is 150° C.

8. The method as claimed in claim 1, wherein the micro-pattern of the brightness enhanced film is a brightened element with a prism structure for gathering light.

9. (canceled)

10. A method for manufacturing a light-concentrating film on a solar cell prepared by an imprint molding process, comprising:
(S1): applying an optical layer directly on a surface of a solar cell;
(S2): heating a substrate of the solar cell at a temperature ranging from 100° C. to 200° C.;
(S3): subsequent to the heating, imprinting a micro-pattern of a brightness enhanced film (BEF) on the optical layer in a vacuum environment, wherein the micro-pattern has a triangular pyramid shape and is periodically arranged on the optical layer; and
(S4): removing the BEF after cooling so that the optical layer is formed into a light-concentrating film corresponding to the micro-pattern of the BEF to complete a method for manufacturing a light-concentrating film on a solar cell;
wherein: (a) the optical layer is horizontally laid on the surface of the solar cell, and (b) the brightness enhanced film is laminated on the optical layer under a pressure ranging from 80 KPa to 100 KPa for 10 to 15 minutes.

11. A method for manufacturing a light-concentrating film on a solar cell prepared by an imprint molding process, comprising:
(S1): applying an optical layer directly on a surface of a solar cell;
(S2): heating a substrate of the solar cell at a temperature ranging from 100° C. to 200° C.;
(S3): subsequent to the heating, imprinting a micro-pattern of a brightness enhanced film (BEF) on the optical layer in a vacuum environment, wherein the micro-pattern has a triangular pyramid shape and is periodically arranged on the optical layer; and
(S4): removing the BEF after cooling so that the optical layer is formed into a light-concentrating film corresponding to the micro-pattern of the BEF to complete a method for manufacturing a light-concentrating film on a solar cell;
wherein the micro-pattern of the brightness enhanced film has a periodical pitch ranging from 17 μm to 48 μm.
